(19) United States
(12) Patent Application Publication
(10) Pub. No.: US 2013/0162252 A1
(43) Pub. Date: Jun. 27, 2013

(54) MR HF COILS HAVING FLEXIBILITY THAT CAN BE MODULATED

(71) Applicant: Oliver Heid, Erlangen (DE)

(72) Inventor: Oliver Heid, Erlangen (DE)

(21) Appl. No.: 13/704,533

(22) PCT Filed: May 31, 2011
(86) PCT No.: PCT/EP11/58902

§ 371 Date: Mar. 7, 2013

(30) Foreign Application Priority Data
Jun. 15, 2010 (DE) 10 2010 023 844.9

(51) Int. Cl. G01R 33/34

(52) U.S. Cl. CPC G01R 33/34084
USPC 324/318

(57) ABSTRACT

The invention relates to a local coil arrangement (6) for an imaging system (1), wherein the local coil arrangement (6) is rigid in a first state, wherein the local coil arrangement (6) is flexible is a second state, wherein the local coil arrangement (6) comprises a reinforcing arrangement (W; S) by which (W; S) the local coil arrangement (6) can be brought from the flexible state into the rigid state, and by which (W; S) the local coil arrangement (6) can be brought from the rigid state to the flexible state.

The present patent document is a §371 nationalization of PCT Application Serial Number PCT/EP2011/058902, filed May 31, 2011, designating the United States, which is hereby incorporated by reference. This patent document also claims the benefit of DE 10 2010 023 844.9, filed on Jun. 15, 2010, which is also hereby incorporated by reference.

### BACKGROUND

The present embodiments relate to a local coil arrangement.

Magnetic resonance devices for examining objects or patients using magnetic resonance tomography are known, for example, from DE 10314215B4.

Modern magnetic resonance systems operate using coils to emit high frequency pulses for nuclear resonance excitation and to receive induced magnetic resonance signals. A magnetic resonance system (MRT or MR) may have a larger whole body coil (e.g., body coil or BC) that may be permanently integrated in the device, as well as a local coil arrangement having one or more local coils (e.g., smaller local coils; also known as surface coils or LC).

Images may be recorded in MR tomography using local coil arrangements. In such arrangements, excited nuclei of an examination object induce a voltage into at least one local coil. The induced voltage is then amplified with a low-noise preamplifier and is transferred via cables or wirelessly to receive electronics of an MRT.

### SUMMARY

The present embodiments may obviate one or more of the drawbacks or limitations in the related art. For example, a local coil arrangement may be further optimized for an imaging system (e.g., a magnetic resonance tomography (MRT) imaging system).

### BRIEF DESCRIPTION OF THE DRAWINGS

FIG. 1 shows one embodiment of a magnetic resonance tomography (MRT) system;

FIG. 2 shows a cross-section through a leg of a patient, upon which one embodiment of a coil arrangement lies, the moveable elements of which may be fixed relative to one another using a cable pull through the elements; and

FIG. 3 shows a flexible sack that may be evacuated in order to fix coil elements of one embodiment of a local coil arrangement relative to one another.

### DETAILED DESCRIPTION OF THE DRAWINGS

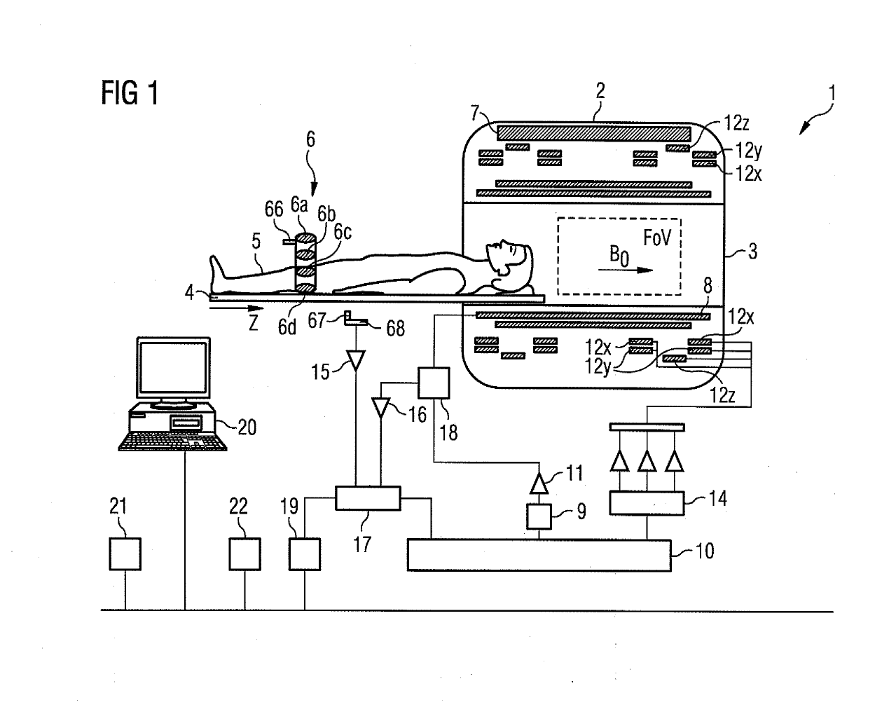

FIG. 1 shows an imaging magnetic resonance device MRT 1 having a whole body coil 2 with, for example, a tubular space 3, in which a patient couch 4 with a body (e.g., a body of a patient with or without local coil arrangement 6) may be moved in the direction of arrow z in order to generate recordings of a patient 5. The local coil arrangement 6 is placed on the patient 5, for example. Good recordings are enabled in a local area (e.g., a field of view) with the local coil arrangement 6. Signals of the local coil arrangement 6 may be evaluated (e.g. converted into images and stored or displayed) by an evaluation device (e.g., elements 67, 66, 15, 17) of the MRT 1 that may be connected to the local coil arrangement 6 by way of coaxial cables or wirelessly, for example.

In order to examine the body 5 (e.g., an examination object or a patient) using the magnetic resonance device MRT 1 by a magnetic resonance imaging, different magnetic fields that are attuned as accurately as possible to one another in terms of temporal and spatial characteristics are radiated onto the body 5. A strong magnet (e.g., a cryomagnet 7 in a measurement cabin with the tunnel-shaped opening 3) generates a strong static main magnetic field B₀ that amounts, for example, to 0.2 tesla to 3 Tesla or even more. The body 5 to be examined supported on the patient couch 4 is moved into an approximately homogenous area of the main magnetic field B₀ in the field of view FOV. Excitation of the nuclear spin of atom nuclei of the body 5 takes place by way of high frequency magnetic excitation pulses that are irradiated by way of a high frequency antenna (and/or if necessary, a local coil arrangement) shown in FIG. 1 in simplified form as a body coil 8. High frequency excitation pulses are generated, for example, by a pulse generation unit 9 that is controlled by a pulse sequence control unit 10. After amplification by a high frequency amplifier 11, the high frequency excitation pulses are routed to the high frequency antenna 8. The high frequency system shown in FIG. 1 is only indicated schematically. More than one pulse generation unit 9, more than one high frequency amplifier 11 and a number of high frequency antennas 8 may be used in a magnetic resonance device 1.

The magnetic resonance device 1 also has gradient coils 12x, 12y, 12z, with which, during a measurement, magnetic gradient fields are irradiated for selective layer excitation and local encoding of the measuring signal. The gradient coils 12x, 12y and 12x are controlled by a gradient coil control unit 14 that, similarly to the pulse generation unit 9, is connected to the pulse sequence control unit 10.

The signals emitted by the excited nuclear spin are received by the body coil 8 and/or at least one local coil arrangement 6, amplified by assigned high frequency preamplifier 16 and further processed and digitalized by a receive unit 17. The recorded measurement data is digitalized and stored as complex numerical values in a k-space matrix. An associated MR image may be reconstructed from the k-space matrix occupied with values using a multidimensional Fourier transform. With a coil that may be operated both in the transmit and also in the receive mode (e.g., the body coil 8), the correct signal forwarding is controlled by an upstream transmit-receive switch 18.

An image processing unit 19 generates an image from the measurement data, which is displayed to a user by way of a control console 20 and/or is stored in a storage unit 21. A central computing unit 22 controls the individual system components.

In MR tomography, images with a high signal-to-noise ratio (SNR) may be recorded using local coil arrangements (e.g., coils, local coils). The local coil arrangements are antenna systems that are attached in the immediate vicinity on (e.g., anterior), below (e.g., posterior), or in the body. With an MR measurement, the excited cores induce a voltage into the individual antennas of the local coil. The induced voltage is amplified with a low-noise preamplifier (e.g., LNA, Preamp) and is transferred to the receive electronics. In order to improve the signal-to-noise ratio even with highly resolved images, high field systems are used (e.g., 1.5 T and more). Since more individual antennas may be connected to an MR receive system than there are receivers present, a switching matrix (e.g., RCCS) is integrated between the receive antennas and the receiver. This routes the currently active receive channels (e.g., the receive channels lying directly in the field of view of the magnet) onto the available receiver. This enables more coil elements to be connected than there are receivers present, since with a whole body coverage, only the coils that are located in the FoV or in the homogeneity volume of the magnet are to be read out.

An antenna system may be referred to as local coil arrangement 6, which may include, for example, one or several antenna elements 6a,6b,6c,6d (e.g., coil elements) as an array coil. These individual antenna elements are embodied, for example, as loop antennas (e.g., loops) or butterfly or saddle coils. A local coil arrangement includes, for example, coil elements, a preamplifier, further electronics (e.g., a coaxial choke), a housing, overlays and may include a cable with a plug, through which the local coil arrangement is connected to the MRT system. A receiver 68 attached on the system side filters and digitizes a signal received by a local coil 6 (e.g., by radio) and transfers the data to a digital signal processing device that may derive an image or a spectrum from the data obtained by a measurement and make the image or the spectrum available to a user (e.g. for subsequent diagnosis thereby or storage).

The present embodiments relate, for example, to MR HF coils that are flexible during the positioning of a patient and are rigid during the measurement.

Such local coil arrangements according to the prior art are either rigid or flexible. Rigid coils are relatively uncomfortable, since a patient is to accept a forced body posture, but nevertheless offer a fixed measuring geometry and thereby prevent motion artifacts during the measurement. Flexible coils allow for a movement of the coils and/or the patient and produce motion artifacts during the imaging, since the patient obtains no tactile feedback relating to his/her body position.

One embodiment includes a coil carrier that is arbitrarily variable in terms of rigidity so that the patient may accept a comfortable body posture, and motion artifacts are consequently prevented. A temporal variable rigidity of the coil arrangement is achieved.

The coil carrier may, for example, include a number of coil elements (e.g., arranged in a network configuration) that rub against one another, and/or the surfaces of the coil elements are toothed, and/or the contact pressure of the coil elements may be adjusted.

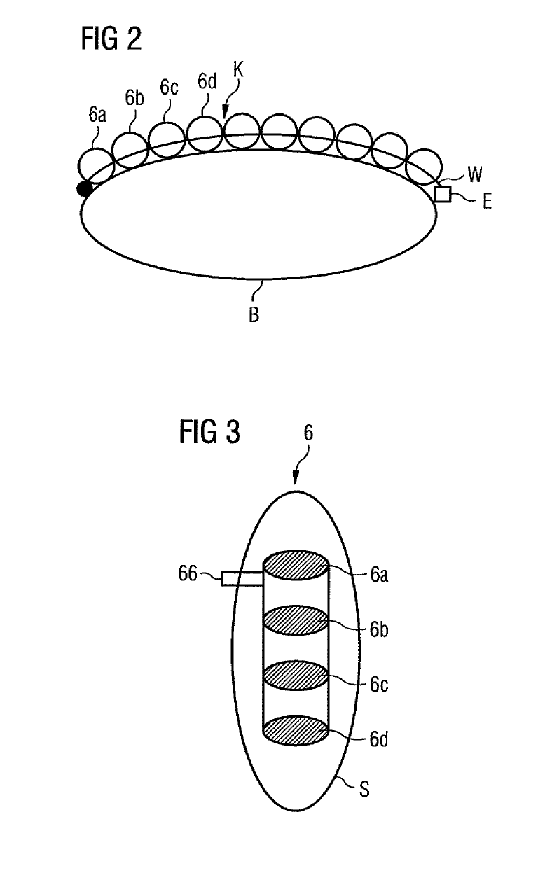

In a flexible state of a coil arrangement 6, which in FIG. 2 rests on a leg B of a patient, elements 6a-6d of the coil arrangement 6 are mounted or moved against one another. In a rigid or pre-tensioned state of the elements 6a-6d of the coil arrangement 6, the last spatial arrangement of the coil elements assumed relative to one another is rigid, so that the coil elements may not be moved relative to one another or are largely immoveable.

Contact pressure to achieve a rigid state of the local coil arrangement 6 may be applied, for example, according to FIG. 2, by pulling on a cable W (e.g., using a schematically indicated eccentric lock E). The cable W passes through the contact surfaces K (on which coil elements rest against one another) of the coil elements 6a-6d. An arrangement of the coil elements 6a-6d may be provided, as in FIG. 2, in a one-dimensional manner with at least a cable or, for example, with one or more cables in a two-dimensional network configuration, so that coil elements are fixed two-dimensionally relative to one another in a state flexible relative to one another (e.g., a moveable state) or in a rigid state.

The coil arrangement 6 brought into a rigid state by pulling on a cable W, for example, may be brought into a flexible state by loosening the cable W using the eccentric lock E, in which the elements of the coil arrangement 6 may be moved relative to one another

Coil elements (e.g., flexibly or rigidly fixed in relation to one another depending on the state) may be any given elements in a coil arrangement (e.g., elements that contain coils or holding elements, support elements, cushioning).

Alternatively, the entire coil arrangement 6 or elements 6a-6d in the coil arrangement may be disposed in a flexible sack S indicated in FIG. 3, which, if the sack S obtains a vacuum relative to the surroundings (e.g., is completely or partially evacuated) rests on the coil elements of the coil and thus, as a reinforcing arrangement, reinforces these relative to one another. If the vacuum in the sack S is cancelled out again by the ingress of air, the coil elements are once again moveable relative to one another in a flexible state.

A reinforcing arrangement (W; S) may be embodied, as described, as a cable W, an evacuatable sack S, or also in any other manner.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A local coil arrangement for an imaging system, wherein the local coil arrangement is rigid in a first state, and wherein the local coil arrangement is flexible in a second state, the local coil arrangement comprising:
a reinforcing arrangement, by which the local coil arrangement is transformable from the flexible state into the rigid state, and by which the local coil arrangement is transformable from the rigid state into the flexible state.

2. The local coil arrangement as claimed in claim 1, further comprising elements that are flexible relative to one another,
wherein the elements are reinforceable relative to one another.

3. The local coil arrangement as claimed in claim 1, further comprising a plurality of coil elements.

4. The local coil arrangement as claimed in claim 1, further comprising a plurality of coil elements that are arranged in a network configuration.

5. The local coil arrangement as claimed in claim 1, further comprising a plurality of coil elements that rub against one another during a movement relative to one another.

6. The local coil arrangement as claimed in claim 1, further comprising a plurality of coil elements, a surface of the plurality of coil elements being toothed.

7. The local coil arrangement as claimed in claim 1, further comprising a plurality of coil elements, a contact pressure of the plurality of coil elements being adjustable.

8. The local coil arrangement as claimed in claim 1, wherein a contact pressure that, in the rigid state, fixes coil elements of the local coil arrangement relative to one another, exists as a pull on a cable that connects the coil elements to one another.

9. The local coil arrangement as claimed in claim 1, wherein a contact pressure that, in the rigid state, fixes coil elements of the local coil arrangement relative to one another, is generatable by an eccentric lock.

10. The local coil arrangement as claimed in claim 1, wherein the local coil arrangement or parts of the local coil arrangement are located in a flexible sack, evacuation of the flexible sack operable to reinforce the local coil arrangement bring the local coil arrangement from the flexible state into the rigid state.

11. The local coil arrangement as claimed in claim 1, wherein the local coil arrangement is a magnetic resonance tomography local coil arrangement.

12. The local coil arrangement as claimed in claim 3, wherein the plurality of coil elements are arranged in a network configuration.

13. The local coil arrangement as claimed in claim 3, wherein the plurality of coil elements rub against one another during a movement relative to one another.

14. The local coil arrangement as claimed in claim 4, wherein the plurality of coil elements rub against one another during a movement relative to one another.

15. The local coil arrangement as claimed in claim 3, wherein a surface of the plurality of coil elements is toothed.

16. The local coil arrangement as claimed in claim 4, wherein a surface of the plurality of coil elements is toothed.

17. The local coil arrangement as claimed in claim 5, wherein a surface of the plurality of coil elements is toothed.

18. The local coil arrangement as claimed in claim 3, wherein a contact pressure of the plurality of coil elements is adjustable.

19. The local coil arrangement as claimed in claim 4, wherein a contact pressure of the plurality of coil elements is adjustable.

20. The local coil arrangement as claimed in claim 5, wherein a contact pressure of the plurality of coil elements is adjustable.
